(19) United States
(12) Patent Application Publication
(10) Pub. No.: US 2026/0190304 A1
(43) Pub. Date: Jul. 2, 2026

(54) WIRELESS CHARGING DEVICE

(71) Applicant: Primax Electronics Ltd., Taipei (TW)

(72) Inventor: Bo-An Chen, Taipei (TW)

(21) Appl. No.: 19/198,842

(22) Filed: May 5, 2025

Related U.S. Application Data
(60) Provisional application No. 63/738,903, filed on Dec. 26, 2024.

(51) Int. Cl. H05K 7/20; H02J 7/00

(52) U.S. Cl. CPC H05K 7/20909; H02J 7/70

(57) ABSTRACT

A wireless charging device includes a housing, a mainboard, an airflow guide cover, a first linking mechanism and a second linking mechanism. A first charging module and the second charging module are disposed on a top side of the mainboard. A fan is installed on a bottom side of the mainboard. The airflow guide cover is assembled with the bottom side of the mainboard. The airflow guide cover includes an air inlet, an accommodation area, a first airflow guide channel, a first fin set, a second airflow guide channel and a second fin set. When an object is placed on the wireless charging device, the first linking mechanism or the second linking mechanism is triggered. The airflow produced by the fan is guided to the bottom side and the two lateral sides of the charged object. Consequently, the cooling and heat dissipation efficacy is enhanced.

### CROSS-REFERENCE TO RELATED APPLICATION

This application claims priority to U.S. Provisional Patent Application No. 63/738,903 filed Dec. 26, 2024, the contents of which are incorporated herein by reference.

### FIELD OF THE INVENTION

The present invention relates to a wireless charging device, and more particularly to a wireless charging device having the function of simultaneously or separately cooling two objects to be charged.

### BACKGROUND OF THE INVENTION

Nowadays, wireless charging devices are widely installed in vehicles. Generally, a fan is used to blow air directly onto the front of the to-be-charged object (e.g., a mobile phone) to achieve the cooling purpose. However, since the heat generation site of the mobile phone is usually concentrated on the back near the charging coil, the existing heat dissipation method of directly blowing the front of the mobile phone cannot effectively cool down the mobile phone. In addition, the existing heat dissipation method of directly blowing the front of the mobile phone cannot meet the heat dissipation requirements when two mobile phones need to be charged at the same time.

### SUMMARY OF THE INVENTION

In order to overcome the drawbacks of the conventional technologies, the present invention provides a wireless charging device. The wireless charging device can be installed in a vehicle to simultaneously charge two mobile phones while cooling the two mobile phones. The wireless charging device of the present invention is equipped with a linking mechanism. When a mobile phone is placed on the wireless charging device, the linking mechanism is triggered. Consequently, the airflow produced by the fan is allowed to be smoothly transferred to the bottom side and the two lateral sides of the mobile phone. Since the two lateral sides of the mobile phone are closer to the position where the charging coil is set on the back of the mobile phone, the cooling and heat dissipation efficacy can be effectively enhanced.

In accordance with an aspect of the present invention, a wireless charging device is provided. The wireless charging device includes a housing, a mainboard, an airflow guide cover, a first linking mechanism and a second linking mechanism. The housing includes an air inlet. An inner space is defined by the housing. The mainboard is disposed within the inner space. The mainboard includes a first charging module, a second charging module and a fan. The first charging module and the second charging module are disposed on a top side of the mainboard. The fan is installed on a bottom side of the mainboard. The airflow guide cover is assembled with the bottom side of the mainboard. The airflow guide cover includes an air inlet, an accommodation area, a first airflow guide channel, a first fin set, a second airflow guide channel and a second fin set. The air inlet of the airflow guide cover is in communication with the air inlet of the housing. The fan is accommodated within the accommodation area. The first airflow guide channel is located under the first charging module. The first fin set is arranged between the accommodation area and the first airflow guide channel. The second airflow guide channel is located under the second charging module. The second fin set is arranged between the accommodation area and the second airflow guide channel. The first linking mechanism is located under the mainboard. The first linking mechanism includes a first cam, a first press rod and a first sliding fence. The first cam includes a force-exerting portion and a resisting portion. The first press rod has a first end and a second end. The first end of the first press rod is penetrated upwardly through the mainboard and exposed outside. The second end of the first press rod presses against the force-exerting portion of the first cam. The first sliding fence is arranged between the first fin set and the first airflow guide channel. The first sliding fence presses against the resisting portion of the first cam. When the first sliding fence is linked with the first press rod, an airflow connection between the first fin set and the first airflow guide channel is selectively closed or opened. The second linking mechanism is located under the mainboard. The second linking mechanism includes a second cam, a second press rod and a second sliding fence. The second cam includes a force-exerting portion and a resisting portion, the second press rod has a first end and a second end. The first end of the second press rod is penetrated upwardly through the mainboard and exposed outside. The second end of the second press rod presses against the force-exerting portion of the second cam. The second sliding fence is arranged between the second fin set and the second airflow guide channel. The second sliding fence presses against the resisting portion of the second cam. When the second sliding fence is linked with the second press rod, an airflow connection between the second fin set and the second airflow guide channel is selectively closed or opened.

In an embodiment, when an object to be charged is placed on the housing to press down the first end of the first press rod, the airflow connection between the first fin set and the first airflow guide channel is opened.

In an embodiment, the wireless charging device further includes a first position-returning element, and the first cam further includes a rotation shaft. The rotation shaft is arranged between the force-exerting portion and the resisting portion of the first cam. The first position-returning element is sheathed around the rotation shaft of the first cam. When the first cam is rotated in response to an external force, the first position-returning element stores an elastic potential energy. After the elastic force is eliminated, the elastic potential energy is released. Consequently, the first cam is returned to an original position.

In an embodiment, the wireless charging device further includes a second position-returning element. The second position-returning element presses against the first sliding fence. The first sliding fence is returned to an original position in response to a restoring force of the second position-returning element.

In an embodiment, the wireless charging device further include a first airflow deflector, and the first airflow deflector is located over the first charging module to cover the first charging module. The first airflow deflector includes a left diverting channel and a right diverting channel.

In an embodiment, the first airflow guide channel includes an inner duct, a central duct and an outer duct. The inner duct of the first airflow guide channel is in communication with the left diverting channel of the first airflow deflector. The outer duct of the first airflow guide channel is in communication with the right diverting channel of the first airflow deflector.

In an embodiment, the wireless charging device further include a second airflow deflector, and the second airflow deflector is located over the second charging module to cover the second charging module. The second airflow deflector includes a left diverting channel and a right diverting channel.

In an embodiment, the second airflow guide channel includes an inner duct, a central duct and an outer duct. The inner duct of the second airflow guide channel is in communication with the right diverting channel of the second airflow deflector. The outer duct of the second airflow guide channel is in communication with the left diverting channel of the second airflow deflector.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the structure of a wireless charging device according to an embodiment of the present invention;

FIG. 2 schematically illustrates two mobile phones and the wireless charging device shown in FIG. 1, in which one mobile phone is being charged and the other mobile phone is not being charged;

FIG. 3 is a schematic exploded view illustrating the wireless charging device shown in FIG. 1;

FIG. 4 is a schematic exploded view illustrating the wireless charging device shown in FIG. 1 and taken along another viewpoint;

FIG. 5 is a schematic perspective view illustrating the combination of a first airflow deflector, a second airflow deflector, a mainboard, an airflow guide cover, a first linking mechanism and a second linking mechanism in the wireless charging device shown in FIG. 3;

FIG. 6 is a schematic exploded view illustrating the first airflow deflector, the second airflow deflector, the mainboard, the airflow guide cover, the first linking mechanism and the second linking mechanism in the wireless charging device shown in FIG. 5;

FIG. 7 is a schematic exploded view illustrating the mainboard, the airflow guide cover, the first linking mechanism and the second linking mechanism in the wireless charging device shown in FIG. 6 and taken along another viewpoint;

FIG. 8 is a schematic perspective view illustrating the relationship between the first linking mechanism, the second linking mechanism and a fan in the wireless charging device according to the embodiment of the present invention;

FIG. 9 is a schematic perspective view illustrating the relationship between the second airflow deflector, a portion of the second airflow deflector, the fan and the airflow guide cover, in which the mainboard and the first airflow deflector are not shown to clearly indicate the corresponding structures of the fan and the airflow guide cover;

FIG. 10 is a schematic cutaway view illustrating a portion of the wireless charging device shown in FIG. 5 and taken along the line A-A; and

FIG. 11 is a schematic cutaway view illustrating another portion of the wireless charging device shown in FIG. 5 and taken along the line A-A.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. In the embodiments of the present invention, the terms “first” and “second” are used to describe the technical content of the present invention, but cannot be understood as indicating or implying relative importance or implicitly indicating the number of the indicated technical features. Furthermore, in the embodiments of the present invention, directional terms such as “up”, “down”, “left” and “right” are defined relative to the positions of the components in the drawings. These directional terms are relative concepts and can be adjusted or changed accordingly according to the positions of the components in actual applications.

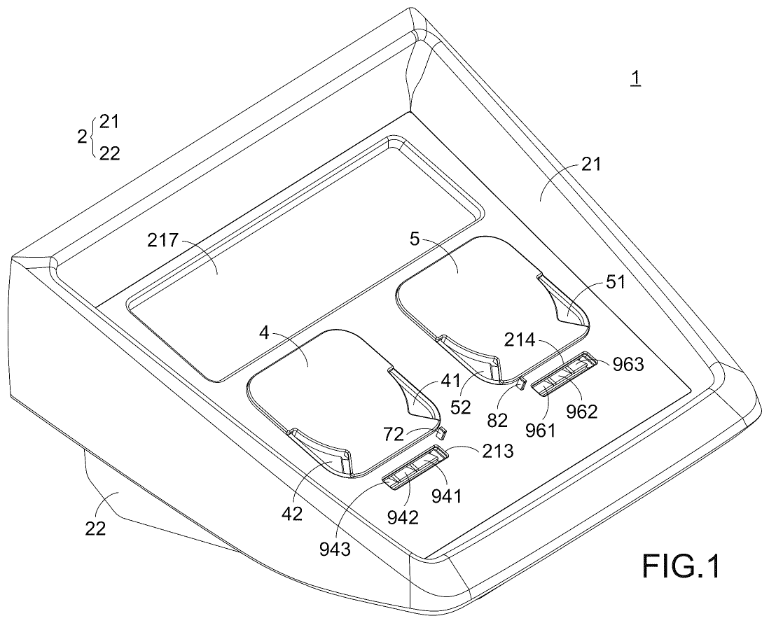

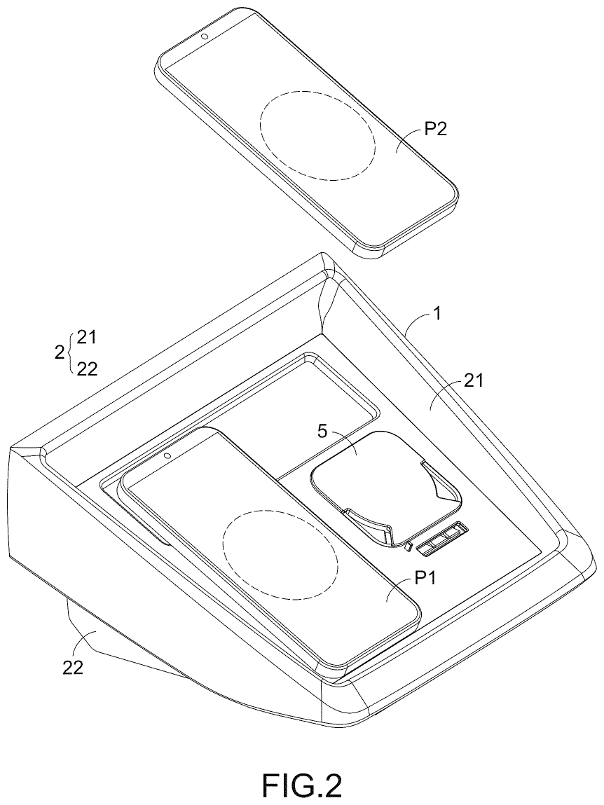

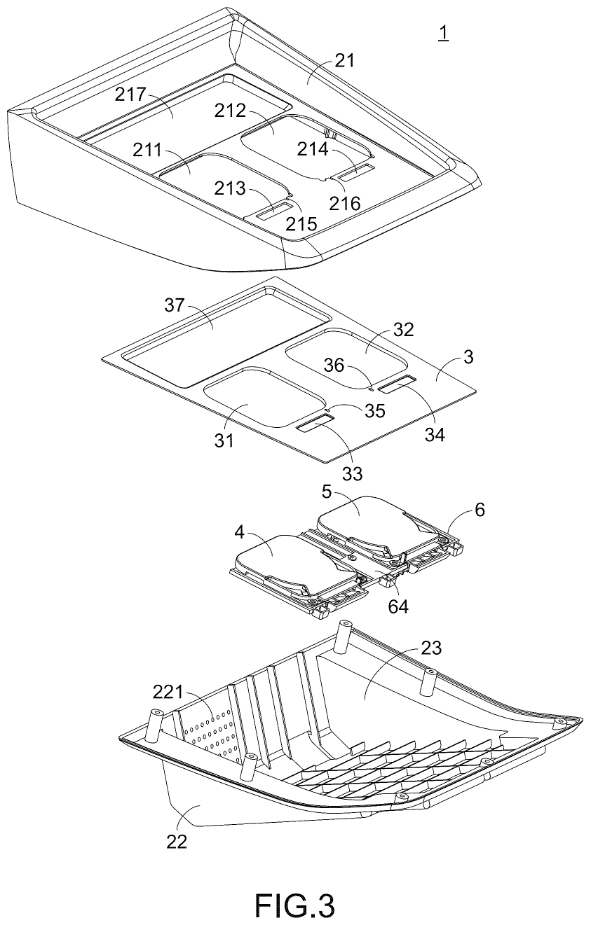

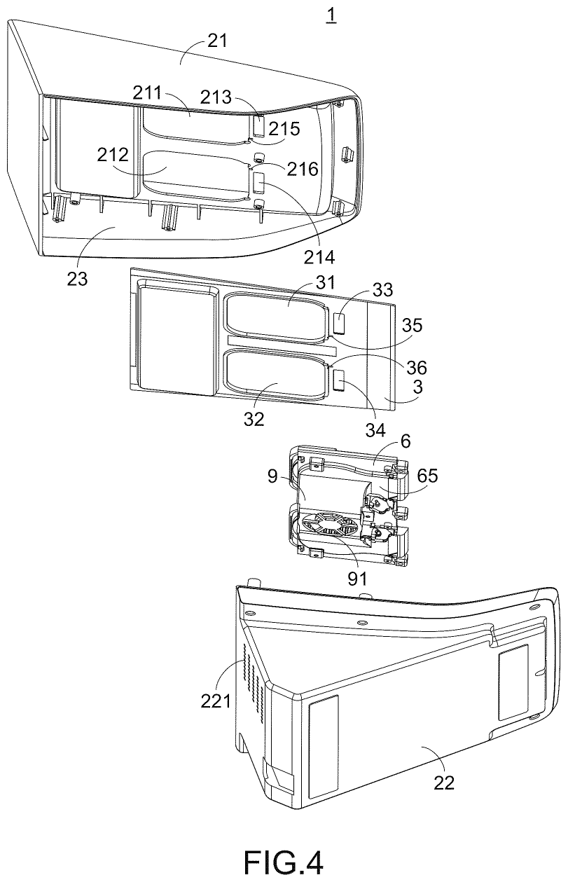

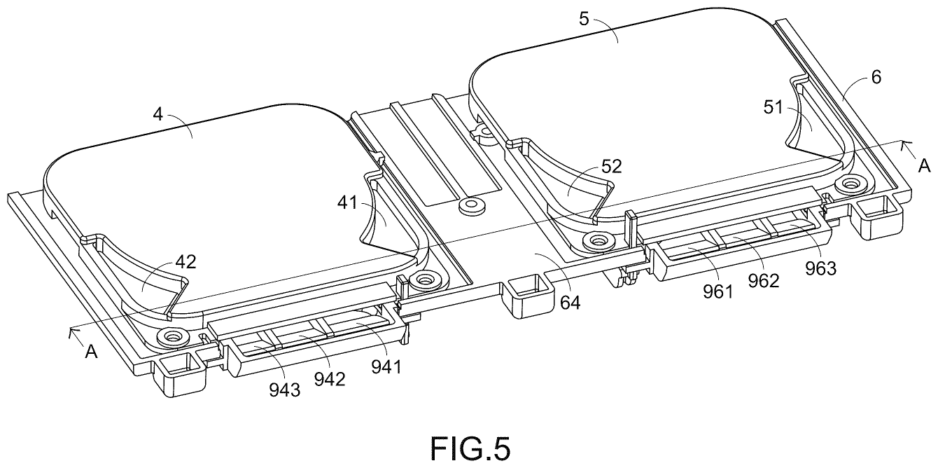

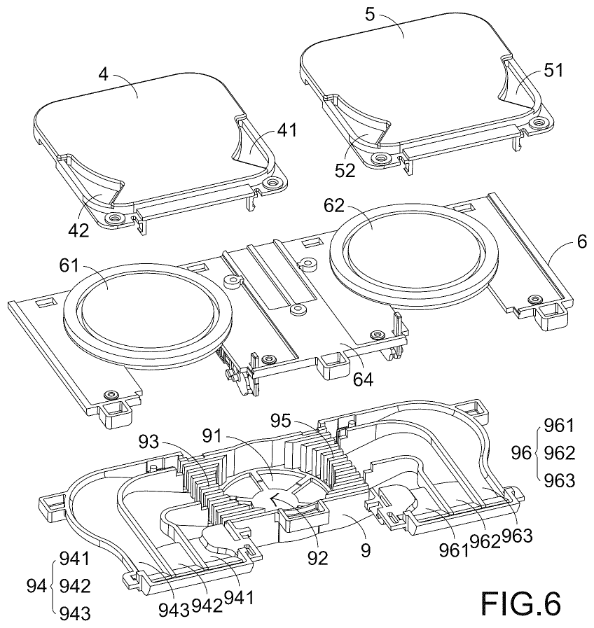

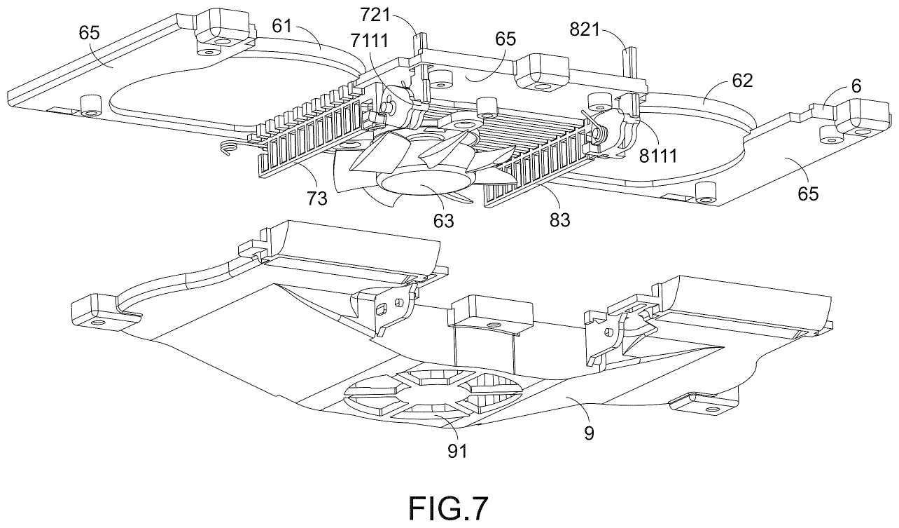

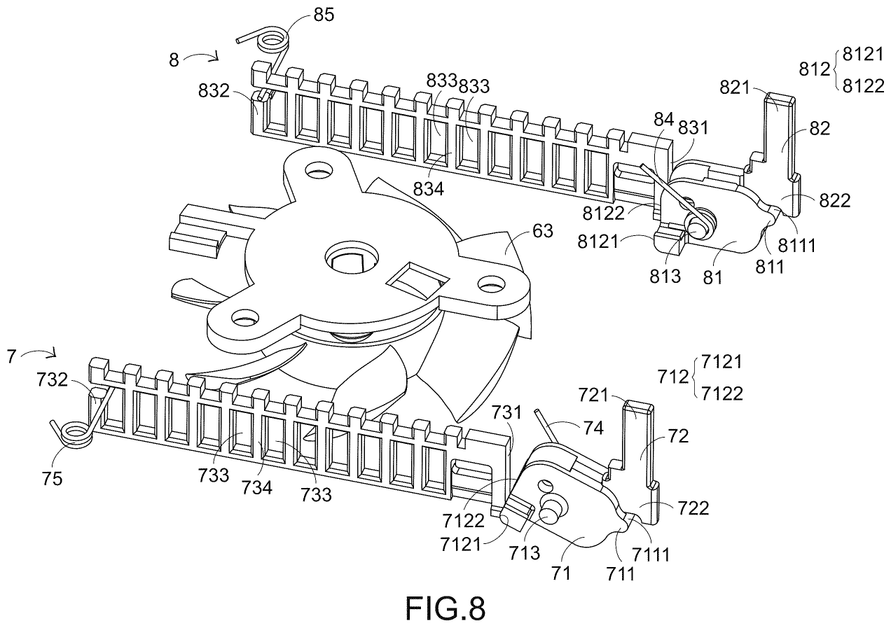

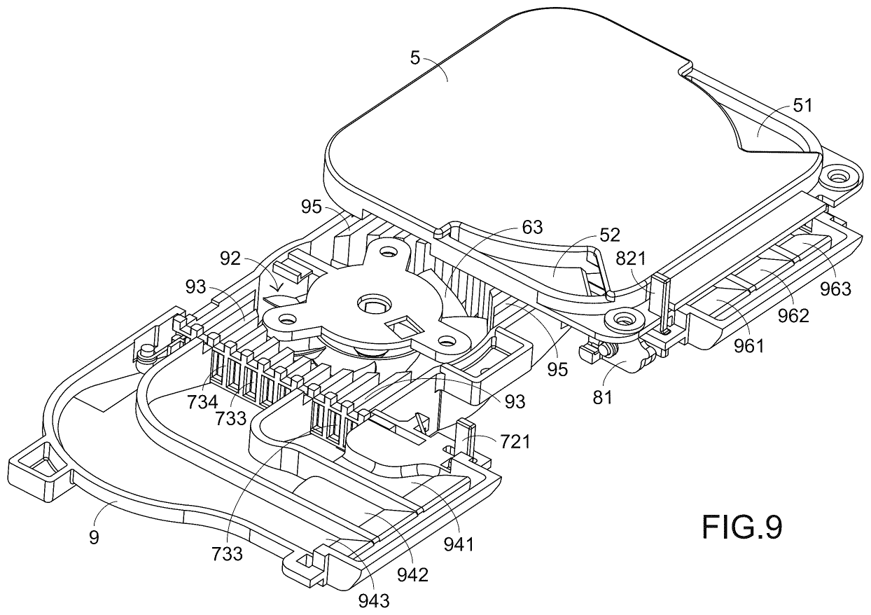

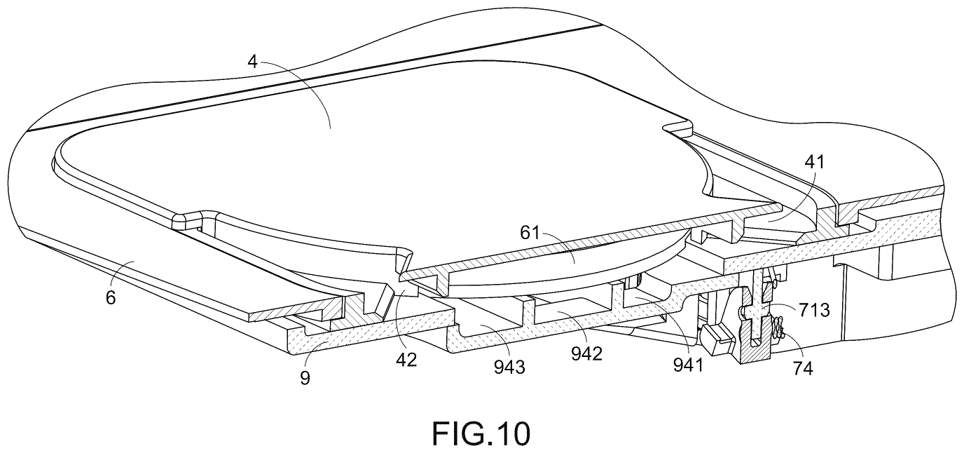

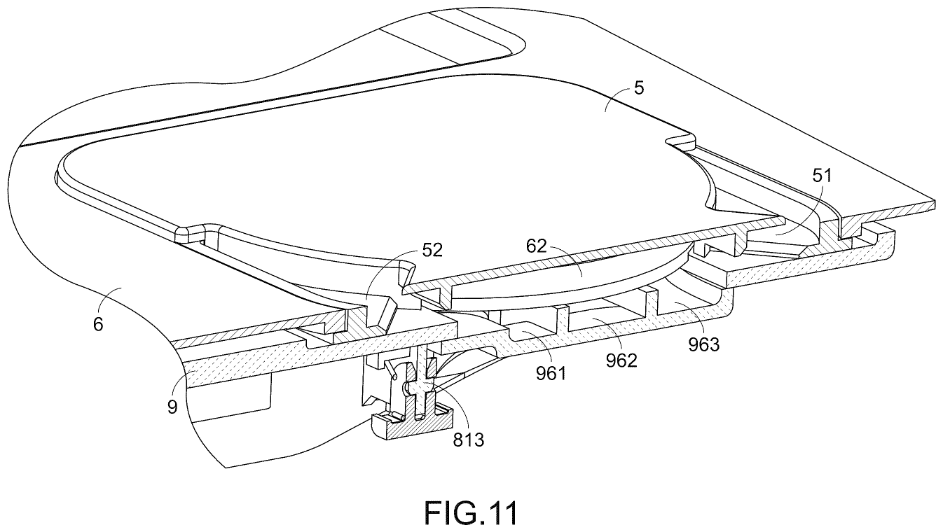

The present invention provides a wireless charging device. FIG. 1 is a schematic perspective view illustrating the structure of a wireless charging device according to an embodiment of the present invention. FIG. 2 schematically illustrates two mobile phones and the wireless charging device shown in FIG. 1, in which one mobile phone is being charged and the other mobile phone is not being charged. FIG. 3 is a schematic exploded view illustrating the wireless charging device shown in FIG. 1. FIG. 4 is a schematic exploded view illustrating the wireless charging device shown in FIG. 1 and taken along another viewpoint. FIG. 5 is a schematic perspective view illustrating the combination of a first airflow deflector, a second airflow deflector, a mainboard, an airflow guide cover, a first linking mechanism and a second linking mechanism in the wireless charging device shown in FIG. 3. FIG. 6 is a schematic exploded view illustrating the first airflow deflector, the second airflow deflector, the mainboard, the airflow guide cover, the first linking mechanism and the second linking mechanism in the wireless charging device shown in FIG. 5. FIG. 7 is a schematic exploded view illustrating the mainboard, the airflow guide cover, the first linking mechanism and the second linking mechanism in the wireless charging device shown in FIG. 6 and taken along another viewpoint. FIG. 8 is a schematic perspective view illustrating the relationship between the first linking mechanism, the second linking mechanism and a fan in the wireless charging device according to the embodiment of the present invention. FIG. 9 is a schematic perspective view illustrating the relationship between the second airflow deflector, a portion of the second airflow deflector, the fan and the airflow guide cover, in which the mainboard and the first airflow deflector are not shown to clearly indicate the corresponding structures of the fan and the airflow guide cover. FIG. 10 is a schematic cutaway view illustrating a portion of the wireless charging device shown in FIG. 5 and taken along the line A-A. FIG. 11 is a schematic cutaway view illustrating another portion of the wireless charging device shown in FIG. 5 and taken along the line A-A.

As shown in FIGS. 1 to 11, the wireless charging device 1 includes a housing 2, a cover plate 3, a first airflow deflector 4, a second airflow deflector 5, a mainboard 6, a first linking mechanism 7, a second linking mechanism 8, and an airflow guide cover 9.

The housing 2 includes an upper cover 21 and a lower cover 22. In addition, a plurality of hollow portions 211, 212, 213, 214, 215, and 216 and a recess 217 are formed in the upper cover 21. The lower cover 22 is assembled with the bottom side of the upper cover 21. In addition, at least one air inlet 221 is formed in the lower cover 22.

In an embodiment, an inner space 23 is defined by the upper cover 21 and the lower cover 22 collaboratively. The cover plate 3, the first airflow deflector 4, the second airflow deflector 5, the mainboard 6, the first linking mechanism 7, the second linking mechanism 8 and the airflow guide cover 9 are disposed within the inner space 23.

The cover plate 3 is located under the upper cover 21. In addition, a plurality of hollow portions 31, 32, 33, 34, 35, and 36 and a recess 37 are formed in the cover plate 3. The hollow portions 31, 32, 33, 34, 35, and 36 and the recess 37 are respectively aligned with the hollow portions 211, 212, 213, 214, 215, and 216 and the recess 217. The recess 217 of the upper cover 21 can be used to accommodate a protruding camera lens on the back of mobile phone P1 or P2. Consequently, the phone P1 or P2 can be stably placed on the wireless charging device 1.

The mainboard 6 includes a first charging module 61, a second charging module 62 and a fan 63. The first charging module 61 and the second charging module 62 are disposed on a top side 64 of the mainboard 6. The fan 63 is installed on a bottom side 65 of the mainboard 6. The top side 64 and the bottom side 65 of the mainboard 6 are opposed to each other.

The first airflow deflector 4 is located over the first charging module 61 to cover the first charging module 61. In addition, the first airflow deflector 4 is penetrated upwardly through the hollow portions 31 and 211 and exposed outside. In an embodiment, the first airflow deflector 4 includes a left diverting channel 41 and a right diverting channel 42.

The second airflow deflector 5 is located over the second charging module 62 to cover the second charging module 62. In addition, the second airflow deflector 5 is penetrated upwardly through the hollow portions 32 and 212 and exposed outside. In an embodiment, the second airflow deflector 5 includes a left diverting channel 51 and a right diverting channel 52.

The airflow guide cover 9 is assembled with the bottom side 65 of the mainboard 6. In addition, the fan 63 is enclosed by the airflow guide cover 9. In an embodiment, the airflow guide cover 9 includes an air inlet 91, an accommodation area 92, a first fin set 93, a first airflow guide channel 94, a second fin set 95, and a second airflow guide channel 96.

The air inlet 91 of the airflow guide cover 9 is located beside the accommodation area 92. In addition, the air inlet 91 is in communication with the air inlet 221 of the lower cover 22. Consequently, the external air or airflow can enter the accommodation area 92 through the air inlet 91. After the airflow guide cover 9 is assembled with the mainboard 6, the fan 63 installed on the bottom side of the mainboard 6 is accommodated within the accommodation area 92.

The first fin set 93 and the second fin set 95 are located beside two opposite sides of the accommodation area 92. The first fin set 93 is arranged between the accommodation area 92 and the first airflow guide channel 94. In addition, the first fin set 93 includes a plurality of parallel fins. The airflow generated by the fan 63 in operation is guided to the first airflow guide channel 94 through the gaps between adjacent fins of the first fin set 93. The second fin set 95 is arranged between the accommodation area 92 and the second airflow guide channel 96. The second fin set 95 includes a plurality of parallel fins. The airflow generated by the fan 63 in operation is guided to the second airflow guide channel 96 through the gaps between adjacent fins of the second fin set 95.

The first airflow guide channel 94 is located under the first charging module 61. In an embodiment, the first airflow guide channel 94 includes an inner duct 941, a central duct 942 and an outer duct 943. Please refer to FIG. 3, FIG. 5, FIG. 9 and FIG. 10. The inner duct 941 of the first airflow guide channel 94 is in communication with the left diverting channel 41 of the first airflow deflector 4, the hollow portion 33 of the cover plate 3 and the hollow portion 213 of the housing 2. The central duct 942 is in communication with the hollow portion 33 of the cover plate 3 and the hollow portion 213 of the housing 2. The outer duct 943 is in communication with the right diverting channel 42 of the first airflow deflector 4, the hollow portion 33 of the cover plate 3 and the hollow portion 213 of the housing 2.

The second airflow guide channel 96 is located under the second charging module 62. In an embodiment, the second airflow guide channel 96 includes an inner duct 961, a central duct 962 and an outer duct 963. Please refer to FIG. 3, FIG. 5, FIG. 9 and FIG. 10. The inner duct 961 of the second airflow guide channel 96 is in communication with the right diverting channel 52 of the second airflow deflector 5, the hollow portion 34 of the cover plate 3 and the hollow portion 214 of the housing 2. The central duct 962 is in communication with the hollow portion 34 of the cover plate 3 and the hollow portion 214 of the housing 2. The outer duct 963 communicates simultaneously with the left diverting channel 51 of the second airflow deflector 5, the hollow portion 34 of the cover plate 3 and the hollow portion 214 of the housing 2.

After air enters the internal space 23 of the wireless charging device 1 through the air inlet 221 of the lower cover 22, the air enters the accommodation area 92 through the air inlet 91 of the airflow guide cover 9 and comes into contact with the fan 63. As the fan 63 rotates, the produced airflow passes through the first fin set 93 and the first airflow guide channel 94, and the produced airflow finally exits to the surroundings through the left diverting channel 41 of the first airflow deflector 4, the hollow portion 213 of the housing 2 and the right diverting channel 42 of the first airflow deflector 4. Similarly, as the fan 63 rotates, the produced airflow passes through the second fin set 95 and the second airflow guide channel 96, and the produced airflow finally exits to the surroundings through the left diverting channel 51 of the second airflow deflector 5, the hollow portion 214 of the housing 2 and the right diverting channel 52 of the second airflow deflector 5.

The first linking mechanism 7 is located under the mainboard 6 and arranged near the first charging module 61. In an embodiment, the first linking mechanism 7 includes a first cam 71, a first press rod 72, a first sliding fence 73, a first position-returning element 74 and a second position-returning element 75.

The first cam 71 is pivotally coupled to a position under the mainboard 6. In an embodiment, the first cam 71 includes a force-exerting portion 711, a resisting portion 712 and a rotation shaft 713. The rotation shaft 713 is arranged between the force-exerting portion 711 and the resisting portion 712. In addition, the rotation shaft 713 is mounted on a bracket (not shown) that is formed on the bottom side 65 of the mainboard 6. Consequently, the first cam 71 is rotatable through the rotation shaft 713. The force-exerting portion 711 includes a transverse rod 7111. The resisting portion 712 includes a first outer edge 7121 and a second outer edge 7122. The distance between the first outer edge 7121 and the axis center of the rotation shaft 713 is greater than the distance between the second outer edge 7122 and the axis center of the rotation shaft 713.

The first press rod 72 has a first end 721 and a second end 722. The first end 721 of the first press rod 72 is penetrated upwardly through the mainboard 6, the hollow portion 35 of the cover plate 3 and the hollow portion 215 of the upper cover 21 and is exposed outside. The second end 722 of the first press rod 72 presses against the transverse rod 7111 of the force-exerting portion 711 of the first cam 71. When an object to be charged (e.g., a mobile phone P1) is placed on the wireless charging device 1, the first end 721 of the first press rod 72 is pressed down by the mobile phone P1. As the first end 721 of the first press rod 72 is moved downwardly, the first cam 71 is pressed down by the second end 722 of the first press rod 72. Consequently, the first cam 71 is rotated. In the accompanying drawings of the present invention, the mobile phone P1 mobile phone P1 has been placed on the wireless charging device 1 to press down the first press rod 72.

An example of the first position-returning element 74 is a torsion spring. The first position-returning element 74 is sheathed around the rotation shaft 713 of the first cam 71. When the first cam 71 is rotated in response to an external force (e.g., the external force from the press rod 72), the first position-returning element 74 stores elastic potential energy. After the elastic force is eliminated, the elastic potential energy is released. Consequently, the first cam 71 is returned to its original position.

The first sliding fence 73 includes a first end 731, a second end 732, a plurality of hollow portions 733 and a plurality of connecting portions 734. The plurality of hollow portions 733 are discretely arranged. Each connecting portion 734 is arranged between every two adjacent hollow portions 733. The first end 731 and the second end 732 are opposed to each other. The hollow portions 733 and the connecting portions 734 are arranged between the first end 731 and the second end 732.

The first sliding fence 73 is arranged between the first fin set 93 and the first airflow guide channel 94. The first sliding fence 73 presses against the first outer edge 7121 or the second outer edge 7122 of the resisting portion 712 of the first cam 71. When the first sliding fence 73 is linked with the first press rod 72, the airflow connection between the first fin set 93 and the first airflow guide channel 94 is selectively closed or opened. In this embodiment, the width of the hollow portion 733 is greater than or equal to the distance between two adjacent fins in the first fin set 93, and the width of the connecting portion 734 is less than or equal to the width of a single fin in the first fin set 93. By controlling the horizontal displacement of the first sliding fence 73, the airflow connection between the first fin set 93 and the first airflow guide channel 94 can be blocked, partially blocked, or fully opened.

When the first cam 71 is pressed by the first press rod 72, the first end 731 of the first sliding fence 73 is gradually moved from its initial position in contact with the second outer edge 7122 to the final position in contact with the first outer edge 7121. During the movement process, the first sliding fence 73 is gradually moved away from the first press rod 72. When the first cam 71 is no longer pressed by the first press rod 72, the first end 731 of the first sliding fence 73 is gradually moved from its initial position in contact with the first outer edge 7121 to the final position in contact with the second outer edge 7122. During the movement process, the first sliding fence 73 is gradually moved toward the first press rod 72.

An example of the second position-returning element 75 is a torsion spring. The second position-returning element 75 presses against the first sliding fence 73. For example, the second position-returning element 75 presses against the second end 732 or one of the hollow portions 733 to provide a restoring force to the first sliding fence 73. When the first sliding fence 73 is pressed by the first outer edge 7121 of the first cam 71, the first sliding fence 73 is slid and the second position-returning element 75 stores elastic potential energy. When the first sliding fence 73 is no longer pressed by the first outer edge 7121 of the first cam 71, the elastic potential energy is released. Consequently, the first sliding fence 73 is returned to its original position in response to a restoring force of the second position-returning element 75.

The second linking mechanism 8 is located under the mainboard 6 and arranged near the second charging module 62. In an embodiment, the second linking mechanism 8 includes a second cam 81, a second press rod 82, a second sliding fence 83, a first position-returning element 84 and a second position-returning element 85.

The second cam 81 is pivotally coupled to a position under the mainboard 6. In an embodiment, the second cam 81 includes a force-exerting portion 811, a resisting portion 812 and a rotation shaft 813. The rotation shaft 813 is arranged between the force-exerting portion 811 and the resisting portion 812. In addition, the rotation shaft 813 is mounted on a bracket (not shown) that is formed on the bottom side 65 of the mainboard 6. Consequently, the second cam 81 is rotatable through the rotation shaft 813. The force-exerting portion 811 includes a transverse rod 8111. The resisting portion 812 includes a first outer edge 8121 and a second outer edge 8122. The distance between the first outer edge 8121 and the axis center of the rotation shaft 813 is greater than the distance between the second outer edge 8122 and the axis center of the rotation shaft 813.

The second press rod 82 has a first end 821 and a second end 822. The first end 821 of the second press rod 82 is penetrated upwardly through the mainboard 6, the hollow portion 36 of the cover plate 3 and the hollow portion 216 of the upper cover 21 and is exposed outside. The second end 822 of the second press rod 82 presses against the transverse rod 8111 of the force-exerting portion 811 of the second cam 81. When an object to be charged (e.g., a mobile phone P2) is placed on the wireless charging device 1, the first end 821 of the second press rod 82 is pressed down by the mobile phone P2. As the first end 821 of the second press rod 82 is moved downwardly, the second cam 81 is pressed down by the second end 822 of the second press rod 82. Consequently, the second cam 81 is rotated. In the accompanying drawings of the present invention, the mobile phone P2 mobile phone P2 has not been placed on the wireless charging device 1. In other words, the second press rod 82 has not been pressed.

An example of the first position-returning element 84 is a torsion spring. The first position-returning element 84 is sheathed around the rotation shaft 813 of the second cam 81. When the second cam 81 is rotated in response to an external force (e.g., the external force from the press rod 82), the first position-returning element 84 stores elastic potential energy. After the elastic force is eliminated, the elastic potential energy is released. Consequently, the second cam 81 is returned to its original position.

The second sliding fence 83 includes a first end 831, a second end 832, a plurality of hollow portions 833 and a plurality of connecting portions 834. The plurality of hollow portions 833 are discretely arranged. Each connecting portion 834 is arranged between every two adjacent hollow portions 833. The first end 831 and the second end 832 are opposed to each other. The hollow portions 833 and the connecting portions 834 are arranged between the first end 831 and the second end 832.

The second sliding fence 83 is arranged between the second fin set 95 and the second airflow guide channel 96. The second sliding fence 83 presses against the first outer edge 8121 or the second outer edge 8122 of the resisting portion 812 of the second cam 81. When the second sliding fence 83 is linked with the second press rod 82, the airflow connection between the second fin set 95 and the second airflow guide channel 96 is selectively closed or opened. In this embodiment, the width of the hollow portion 833 is greater than or equal to the distance between two adjacent fins in the second fin set 95, and the width of the connecting portion 834 is less than or equal to the width of a single fin in the second fin set 95. By controlling the horizontal displacement of the second sliding fence 83, the airflow connection between the second fin set 95 and the second airflow guide channel 96 can be blocked, partially blocked, or fully opened.

When the second cam 81 is pressed by the second press rod 82, the first end 831 of the second sliding fence 83 is gradually moved from its initial position in contact with the second outer edge 8122 to the final position in contact with the first outer edge 8121. During the movement process, the second sliding fence 83 is gradually moved away from the second press rod 82. When the second cam 81 is no longer pressed by the second press rod 82, the first end 831 of the second sliding fence 83 is gradually moved from its initial position in contact with the first outer edge 8121 to the final position in contact with the second outer edge 8122. During the movement process, the second sliding fence 83 is gradually moved toward the second press rod 82.

An example of the second position-returning element 85 is a torsion spring. The second position-returning element 85 presses against the second sliding fence 83. For example, the second position-returning element 85 presses against the second end 832 or one of the hollow portions 833 to provide a restoring force to the second sliding fence 83. When the second sliding fence 83 is pressed by the first outer edge 8121 of the second cam 81, the second sliding fence 83 is slid and the second position-returning element 85 stores elastic potential energy. When the second sliding fence 83 is no longer pressed by the first outer edge 8121 of the second cam 81, the elastic potential energy is released. Consequently, the second sliding fence 83 is returned to its original position in response to a restoring force of the second position-returning element 85.

As mentioned above, when an object to be charged (e.g., the mobile phone P1) is placed on the first charging module 61 of the wireless charging device 1 to undergo the charging process, the first press rod 72 of the first linking mechanism 7 is pressed down by the mobile phone P1. As the first press rod 72 is pressed down, the first cam 71 is rotated to drive the lateral movement of the first sliding fence 73. Consequently, the airflow produced by the fan 63 can smoothly pass through the first airflow guide channel 94 and smoothly exit from the left diverting channel 41 of the first airflow deflector 4, the hollow portion 213 of the housing 2 and the right diverting channel 42 of the first airflow deflector 4. In this way, the two lateral sides and the bottom side of the mobile phone P1 can be cooled down. That is, the heat generated by the mobile phone P1 can be effectively dissipated away.

Similarly, when an object to be charged (e.g., the mobile phone P2) is placed on the second charging module 62 of the wireless charging device 1 to undergo the charging process, the second press rod 82 of the second linking mechanism 8 is pressed down by the mobile phone P2. As the second press rod 82 is pressed down, the second cam 81 is rotated to drive the lateral movement of the second sliding fence 83. Consequently, the airflow produced by the fan 63 can smoothly pass through the second airflow guide channel 96 and smoothly exit from the left diverting channel 51 of the second airflow deflector 5, the hollow portion 214 of the housing 2 and the right diverting channel 52 of the second airflow deflector 5. In this way, the two lateral sides and the bottom side of the mobile phone P2 can be cooled down. That is, the heat generated by the mobile phone P2 can be effectively dissipated away.

Generally, the two lateral sides of the mobile phone are closer to the location of the charging coil on the back of the mobile phone. Due to the structural design of the present wireless charging device, the heat generated by the charged object can be effectively removed during the charging process.

From the above descriptions, the present invention provides a wireless charging device. The wireless charging device of the present invention can simultaneously charge two objects (e.g., mobile phones) while cooling the two objects. Furthermore, if only one object is charged, the position of the other object receives little or no airflow from the fan. As a consequence, the cooling efficiency will be enhanced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A wireless charging device, comprising:
a housing comprising an air inlet, wherein an inner space is defined by the housing;
a mainboard disposed within the inner space, and comprising a first charging module, a second charging module and a fan, wherein the first charging module and the second charging module are disposed on a top side of the mainboard, and the fan is installed on a bottom side of the mainboard;
an airflow guide cover assembled with the bottom side of the mainboard, and comprising an air inlet, an accommodation area, a first airflow guide channel, a first fin set, a second airflow guide channel and a second fin set, wherein the air inlet of the airflow guide cover is in communication with the air inlet of the housing, the fan is accommodated within the accommodation area, the first airflow guide channel is located under the first charging module, the first fin set is arranged between the accommodation area and the first airflow guide channel, the second airflow guide channel is located under the second charging module, and the second fin set is arranged between the accommodation area and the second airflow guide channel;
a first linking mechanism located under the mainboard, and comprising a first cam, a first press rod and a first sliding fence, wherein the first cam comprises a force-exerting portion and a resisting portion, the first press rod has a first end and a second end, the first end of the first press rod is penetrated upwardly through the mainboard and exposed outside, the second end of the first press rod presses against the force-exerting portion of the first cam, the first sliding fence is arranged between the first fin set and the first airflow guide channel, and the first sliding fence presses against the resisting portion of the first cam, wherein when the first sliding fence is linked with the first press rod, an airflow connection between the first fin set and the first airflow guide channel is selectively closed or opened; and
a second linking mechanism located under the mainboard, and comprising a second cam, a second press rod and a second sliding fence, wherein the second cam comprises a force-exerting portion and a resisting portion, the second press rod has a first end and a second end, the first end of the second press rod is penetrated upwardly through the mainboard and exposed outside, the second end of the second press rod presses against the force-exerting portion of the second cam, the second sliding fence is arranged between the second fin set and the second airflow guide channel, and the second sliding fence presses against the resisting portion of the second cam, wherein when the second sliding fence is linked with the second press rod, an airflow connection between the second fin set and the second airflow guide channel is selectively closed or opened.

2. The wireless charging device according to claim 1, wherein when an object to be charged is placed on the housing to press down the first end of the first press rod, the airflow connection between the first fin set and the first airflow guide channel is opened.

3. The wireless charging device according to claim 2, wherein the wireless charging device further comprises a first position-returning element, and the first cam further comprises a rotation shaft, wherein the rotation shaft is arranged between the force-exerting portion and the resisting portion of the first cam, and the first position-returning element is sheathed around the rotation shaft of the first cam, wherein when the first cam is rotated in response to an external force, the first position-returning element stores an elastic potential energy, wherein after the elastic force is eliminated, the elastic potential energy is released, so that the first cam is returned to an original position.

4. The wireless charging device according to claim 3, wherein the wireless charging device further comprises a second position-returning element, wherein the second position-returning element presses against the first sliding fence, and the first sliding fence is returned to an original position in response to a restoring force of the second position-returning element.

5. The wireless charging device according to claim 1, wherein the wireless charging device further comprise a first airflow deflector, and the first airflow deflector is located over the first charging module to cover the first charging module, wherein the first airflow deflector comprises a left diverting channel and a right diverting channel.

6. The wireless charging device according to claim 5, wherein the first airflow guide channel comprises an inner duct, a central duct and an outer duct, wherein the inner duct of the first airflow guide channel is in communication with the left diverting channel of the first airflow deflector, and the outer duct of the first airflow guide channel is in communication with the right diverting channel of the first airflow deflector.

7. The wireless charging device according to claim 1, wherein the wireless charging device further comprise a second airflow deflector, and the second airflow deflector is located over the second charging module to cover the second charging module, wherein the second airflow deflector comprises a left diverting channel and a right diverting channel.

8. The wireless charging device according to claim 7, wherein the second airflow guide channel comprises an inner duct, a central duct and an outer duct, wherein the inner duct of the second airflow guide channel is in communication with the right diverting channel of the second airflow deflector, and the outer duct of the second airflow guide channel is in communication with the left diverting channel of the second airflow deflector.
